(19) United States
(12) Patent Application Publication
(10) Pub. No.: US 2026/0118379 A1
(43) Pub. Date: Apr. 30, 2026

(54) TEST SOCKET

(71) Applicants: Dong Weon HWANG, Seongnam-si Gyeonggi-do (KR); Jae Baek HWANG, Seongnam-si Gyeonggi-do (KR); Logan Jae HWANG, Beverly Hills, CA (US); HICON CO., LTD., Seongnam-si Gyeonggi-do (KR)

(72) Inventors: Dong Weon HWANG, Seongnam-si Gyeonggi-do (KR); Jae Baek HWANG, Seongnam-si Gyeonggi-do (KR); Seung Woo RHEE, Seongnam-si Gyeonggi-do (KR)

(21) Appl. No.: 19/401,448

(22) Filed: Nov. 26, 2025

Related U.S. Application Data
(63) Continuation of application No. PCT/KR2025/001660, filed on Feb. 5, 2025.

(30) Foreign Application Priority Data
Oct. 25, 2024 (KR) 10-2024-0147628

(51) Int. Cl. G01R 1/067; G01R 1/073

(52) U.S. Cl. CPC G01R 1/06722; G01R 1/07314

(57) ABSTRACT

Provided is a test socket including a socket body including an elastic insulator and a spring contact inserted into a hole formed in the socket body and having an elastic force in a pressing direction. The test socket is for electrically connecting a plurality of leads provided on a semiconductor device to test the semiconductor device (an integrated circuit (IC) and a pad of a printed circuit board (PCB), or for electrically connecting IC leads such as a central processing unit (CPU) and the like to a PCB in an electronic product such as a computer, mobile phone, or the like.

### TECHNICAL FIELD

The present invention relates to a test socket for electrically connecting a plurality of leads provided on a semiconductor device to test the semiconductor device (an integrated circuit (IC) and a pad of a printed circuit board (PCB), or for electrically connecting IC leads such as a central processing unit (CPU) and the like to a PCB in an electronic product such as a computer, mobile phone, or the like.

### BACKGROUND ART

Generally, a ball grid array (BGA) or land grid array (LGA) type semiconductor integrated circuit (IC) is ultimately subjected to characteristics measurement or defects inspection through various electrical tests by an inspection device. In this case, a test socket is used to electrically connect a circuit pattern of a printed circuit board for inspection installed in the inspection device and lead balls (contact balls) or lands of the BGA type or LGA type semiconductor IC.

A sufficient pressure should be applied to a contact used in the test socket to allow the contact to be in reliable contact with the leads of the IC, and accordingly, the contact should have a sufficient elastic contact force within an appropriate range, and various types of contacts are available to meet these requirements.

Meanwhile, in the test socket, a plurality of spring contacts are installed in a housing according to a certain regulation. Recently, since various semiconductor devices have been developed, customers' requirements for spring contacts having various lengths are increasing, and conventional pogo pin-type spring contacts often fail to meet customers' performance requirements.

For example, when the conventional pogo pin-type spring contact is manufactured with a length long enough to meet customer requirements, a depth of a pin hole into which the spring contact is inserted should be machined with a diameter which accommodates a width of a contact pin tip portion in consideration of the length of the contact pin while increasing a length of a contact pin constituting the spring contact when designing the test socket.

Since the spring contact pin is becoming increasingly miniaturized for faster data processing and reduced power consumption, it is difficult to machine a long pin hole with a diameter which accommodates the width of the contact pin tip portion, and in addition, even when the long pin hole may be machined with a relatively small diameter which accommodates the width of the contact pin tip portion, machining costs are high and it is difficult to guarantee quality.

That is, the conventional spring contacts struggle to meet customer requirements for spring contacts having various lengths.

Meanwhile, there is a rubber-type socket as another conventional technology, and the rubber socket is composed of a flexible insulating body made of solidified insulating silicone, and a conductive silicone portion formed vertically through the insulating body to correspond to the leads of the device.

In the rubber-type socket, when a silicone mixture in which insulating silicone and conductive powder are mixed in a certain ratio is inserted into a mold and a strong magnetic field is applied to a location where the conductive silicone portion is formed, since the conductive powder in the silicone mixture gathers at a position where the magnetic field is formed and the molten silicone mixture is finally solidified, and a conductive silicone portion in a specific arrangement is formed on the insulating body.

The rubber-type socket has a slower elastic response speed compared to the pin-type contact (the spring contact) and has a disadvantage in that service life is significantly short due to loss of elasticity in repeated test processes, and accordingly, the number of uses is short, and cost increases occur due to frequent replacement. Further, due to a characteristic that elastic durability decreases over time, since an elastic rebound force becomes zero or significantly lower during a continuous compression test for a long period of time (for a week or more) and thus a short circuit occurs, the rubber-type socket is unsuitable for long-term testing.

In addition, in the rubber-type socket, there is a problem in that elastic properties are greatly affected by temperature, and the uniformity of resistance may deteriorate due to the mixed insulating silicone or elastomer.

### DISCLOSURE

### Technical Problem

Accordingly, in order to solve the above-described problems, the present invention is directed to providing a test socket in which the advantages of the pogo pin type and the rubber type are combined.

One of the various objects of the present invention is to provide a test socket suitable for testing a high-speed signal semiconductor device. Further, the present invention is directed to providing a test socket whose noise shielding performance between adjacent contact pins and coaxial alignment performance of contact pins are enhanced.

In addition, one of the various objects of the present invention is to provide a test socket capable of minimizing an effect according to a temperature change (temperature stability is high).

One of the various objects of the present invention is to provide a test socket including various types of contact pins to meet customers' performance requirements.

### Technical Solution

Various embodiments for solving the problems of the present invention may provide a test socket including: a base including a first surface facing a lead of a semiconductor device and a second surface facing a pad of a test device; an elastic insulator filled and then hardened in the base to form an elastic force; holes passing through the first surface, the second surface, and the elastic insulator; and a spring contact inserted into the holes and having one end that is in contact with the lead of the semiconductor device and the other end that is in contact with the pad of the test device to exert an elastic force in a pressing direction, wherein the spring contact includes a shoulder having a width greater than diameters of the holes, and the shoulder is in contact with the elastic insulator.

The width of the shoulder may form the maximum width of the spring contact.

The width of the shoulder may be greater than an inner diameter of a spring and smaller than an outer diameter of the spring.

The diameters of the holes formed in the first surface, the second surface, and the elastic insulator may be the same.

The diameters of two holes selected from the diameter of the hole formed in the first surface, the diameter of the hole formed in the second surface, and the diameter of the hole formed in the elastic insulator may be different from each other.

The test socket may further include a first member made of an elastic material provided on an inner surface of the hole formed in the first surface to fix an end portion position of the spring contact.

Various embodiments of the present invention may provide a test socket including: a base including a first surface facing a lead of a semiconductor device and a second surface facing a pad of a test device; an elastic insulator filled and then hardened in the base to form an elastic force; holes passing through the first surface, the second surface, and the elastic insulator; and a spring contact inserted into the holes and having one end that is in contact with the lead of the semiconductor device and the other end that is in contact with the pad of the test device and to exert an elastic force in a pressing direction, wherein the spring contact includes a shoulder having a width greater than at least one of diameters of the holes formed in the first surface, the second surface, and the elastic insulator, and the shoulder is in contact with the elastic insulator.

The diameter of the hole formed in the first surface may be greater than the diameters of the holes formed in the second surface and the elastic insulator.

The diameter of the hole formed in the first surface may be greater than the width of the shoulder.

The diameters of the holes formed in the second surface and the elastic insulator may be smaller than the width of the shoulder.

The test socket may further include a first member made of an elastic material provided on an inner surface of the hole formed in the first surface to fix an end portion position of the spring contact.

The elastic insulator may be provided between an inner surface of the hole formed in the first surface and an end portion of the spring contact.

The test socket may further include a first member made of an elastic material provided on the inner surface of the hole formed in the elastic insulator to fix the end portion position of the spring contact.

An exemplary embodiment of the present invention may provide a test socket including: a base including a first surface facing a lead of a semiconductor device and a second surface facing a pad of a test device; an elastic insulator filled and then hardened in the base to form an elastic force; holes passing through the first surface, the second surface, and the elastic insulator; and a spring contact inserted into the holes and having one end that is in contact with the lead of the semiconductor device and the other end that is in contact with the pad of the test device and to exert an elastic force in a pressing direction, wherein the spring contact includes a spring having a diameter greater than diameters of the holes, and the spring presses an inner surface of the hole formed in the elastic insulator.

The diameter of the spring may form the maximum diameter of the spring contact.

The spring contact may include a head portion that is in contact with the lead of the semiconductor device and the pad of the test device, and the head portion may be formed by rolling a plate-shaped strip.

The maximum diameter of the head portion may be greater than an inner diameter of the spring and smaller than an outer diameter of the spring.

The test socket may further include a first member made of an elastic material provided on an inner surface of the hole formed in the first surface or an inner surface of the hole formed in the second surface to fix an end portion position of the spring contact.

The test socket may further include a first member provided on an inner surface of the hole formed in the first surface and an inner surface of the hole formed in the second surface to fix an end portion position of the spring contact.

An exemplary embodiment of the present invention may provide a test socket including: a base including a first surface facing a lead of a semiconductor device and a second surface facing a pad of a test device; an elastic insulator filled and then hardened in the base to form an elastic force; holes passing through the first surface, the second surface, and the elastic insulator; a spring contact inserted into the holes and having one end that is in contact with the lead of the semiconductor device and the other end that is in contact with the pad of the test device and to exert an elastic force in a pressing direction; and a first member made of an elastic material provided on at least one of an inner surface of the hole formed in the first surface and an inner surface of the hole formed in the second surface to fix an end portion position of the spring contact, wherein the spring contact includes a spring having a diameter smaller than diameters of the holes.

Various embodiments of the present invention provide a test socket including: a base including a first surface facing a lead of a semiconductor device and a second surface facing a pad of a test device; an elastic insulator filled and then hardened in the base to form an elastic force; holes passing through the first surface, the second surface, and the elastic insulator; and a spring contact inserted into the holes and having one end that is in contact with the lead of the semiconductor device and the other end that is in contact with the pad of the test device and to exert an elastic force in a pressing direction, wherein the spring contact includes a shoulder having a width greater than diameters of the holes, and the shoulder is in contact with the base according to the elastic force of the spring contact.

The lead of the semiconductor device may have a pad shape.

The diameter of the hole formed in the first surface may be greater than diameters of the holes formed in the second surface and the elastic insulator.

The diameter of the hole formed in the first surface may be greater than the maximum diameter of the spring contact.

The diameters of the holes formed in the second surface, and the elastic insulator may be the same.

The diameters of the holes formed in the second surface and the elastic insulator may be smaller than the maximum diameter of the spring contact.

The test socket may further include a first member provided on an inner surface of the hole formed in the first surface and an end portion of the spring contact.

The lead of the semiconductor device may have a ball shape.

The first member may be provided to be rolled into and hardened in the hole formed in the first surface and the end portion of the spring contact.

The elastic insulator may be provided between the inner surface of the hole formed in the first surface and the end portion of the spring contact.

The test socket may further include a first member provided on an inner surface of the hole formed in the elastic insulator and an end portion of the spring contact.

The first member may be provided to be rolled into and hardened in the hole formed in the elastic insulator and the end portion of the spring contact.

The lead of the semiconductor device may have a ball shape.

An exemplary embodiment of the present invention provides a test socket including: a base including a first surface facing a lead of a semiconductor device and a second surface facing a pad of a test device; an elastic insulator filled and then hardened in the base to form an elastic force; holes passing through the first surface, the second surface, and the elastic insulator; and a spring contact inserted into the holes and having one end that is in contact with the lead of the semiconductor device and the other end that is in contact with the pad of the test device and to exert an elastic force in a pressing direction, wherein the spring contact includes a spring having a diameter greater than diameters of the holes, and the spring presses an inner surface of the hole formed in the elastic insulator.

The test socket may further include a first member provided on at least one of an inner surface of the hole formed in the first surface and one end of the spring contact and an inner surface of the hole formed in the second surface and the other end of the spring contact.

The first member may be provided to be rolled into and hardened in the inner surface of the hole and the end portion of the spring contact.

The features of each of the above-described embodiments may be implemented in combination in other embodiments as long as the above-described embodiments are not contradictory or exclusive to other embodiments.

### Advantageous Effects

According to various embodiments of the present invention, it is possible to facilitate upper portion contraction control of a socket body made of an elastic insulator.

Further, since physical pins (spring contact pins) are applied, reliability can be enhanced.

In addition, since position alignment of contact pin contact portions provided inside the socket body is easy, the coaxial alignment performance of the contact pins can be enhanced.

In addition, since the insulating performance between fine pitches is enhanced, noise can be reduced when testing a high-speed signal semiconductor device.

In addition, as a silicone member is compressed and hardened at an upper portion of a socket, it is possible to prevent a spring contact inserted into a hole formed in the socket body made of an elastic insulator from being detached.

In addition, it is possible to prevent electrical performance from deteriorating due to foreign substances entering the hole into which the spring contact is inserted or between a printed circuit board (PCB) and the pin in the socket body.

Effects of the present invention are not limited to the above-described effects, and other effects which are not mentioned will be clearly understood by those skilled in the art from the following disclosure.

### DESCRIPTION OF DRAWINGS

FIG. 1 is a view illustrating a test socket for land grid array (LGA) leads according to an exemplary embodiment of the present invention.

FIG. 2 is a view illustrating a test socket for ball grid array (BGA) leads according to the exemplary embodiment of the present invention.

FIGS. 3 to 8 are views illustrating spring contacts applied in FIGS. 1 and 2.

FIG. 9 is a view illustrating a test socket according to the exemplary embodiment of the present invention.

FIGS. 10 to 15 are views illustrating spring contacts applied in FIG. 9.

### MODES OF THE INVENTION

Hereinafter, specific embodiments of the present invention will be described with reference to the drawings. The following detailed description is provided to help comprehensive understanding of the methods, devices, and/or systems described in the present specification. However, this is merely an example, and the present invention is not limited thereto.

In describing the embodiments of the present invention, detailed descriptions of known technology related to the present invention will be omitted when the detailed descriptions is judged to unnecessarily obscure the principle of the present invention. Further, the terms to be described below are terms defined in consideration of functions in the present invention, and may vary depending on the intention, custom, or the like of the user or operator. Accordingly, the definition should be based on the content throughout the present specification.

The terms used in the detailed description are intended only to describe the embodiments of the present invention and should not be restrictive. Unless explicitly used otherwise, the singular form also includes the plural form.

In the description, an expression such as “including” or “providing” is intended to refer to certain characteristics, numbers, steps, operations, elements, and parts or combinations thereof, and should not be interpreted as excluding the presence or possibility of one or more other characteristics, numbers, steps, operations, elements, and parts or combinations thereof other than those described.

Further, terms such as first, second, A, B, (a), (b), and the like may be used to describe components of the embodiments of the present invention. These terms are merely used to distinguish one component from other component(s) and do not limit the nature, order, or sequence of the components.

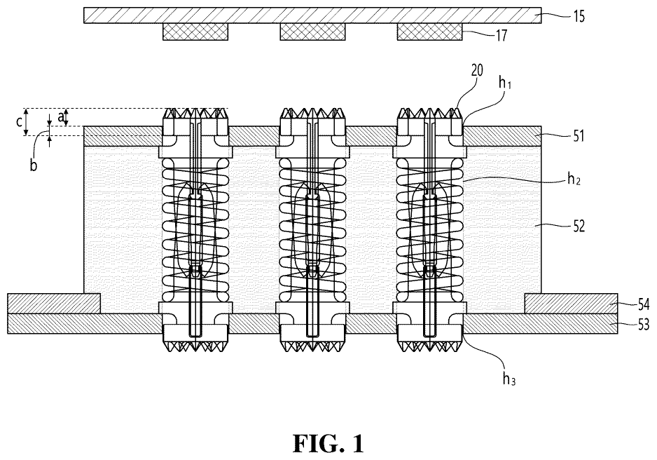

FIG. 1 is a view illustrating a test socket for land grid array (LGA) leads according to an exemplary embodiment of the present invention.

Hereinafter, the present invention will be described with reference to FIG. 1.

The test socket of the embodiment may include a body and a contact 20. The body may be formed of a material having an elastic force when pressed by a semiconductor device, and the contact 20 may be provided with a component having a physically elastic force (for example, a spring) or formed of a material having an elastic force (for example, silicon powder mixed with conductive particles). The contact 20 of the embodiment is a contact including a physically elastic spring, and hereinafter, is referred to as a spring contact.

The body may be formed with holes h₁, h₂, and h₃ passing through a first surface 51 facing a lead of the semiconductor device and a second surface 53 facing a pad of the test device. Since diameters of the holes h₁, h₂, and h₃ are formed to be similar to a diameter of the contact 20, the spring contact 20 may be inserted into the holes h₁, h₂, and h₃.

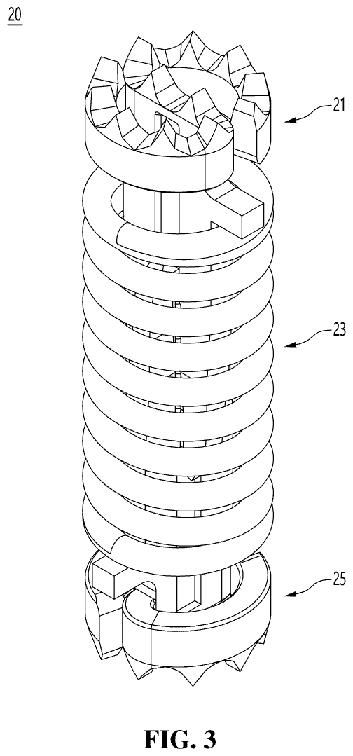

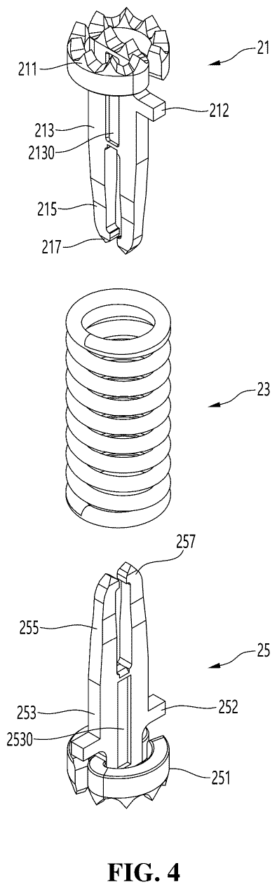

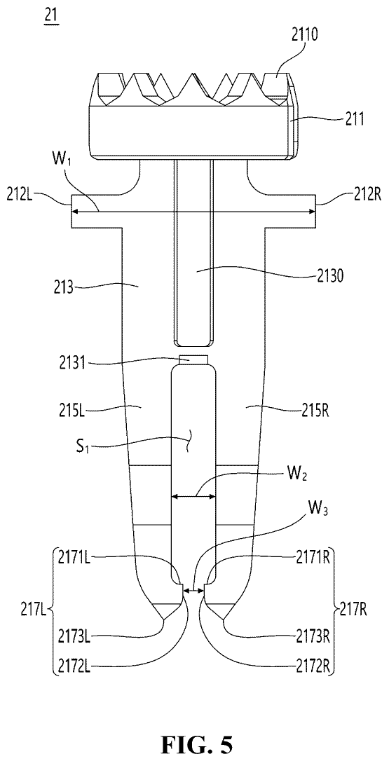

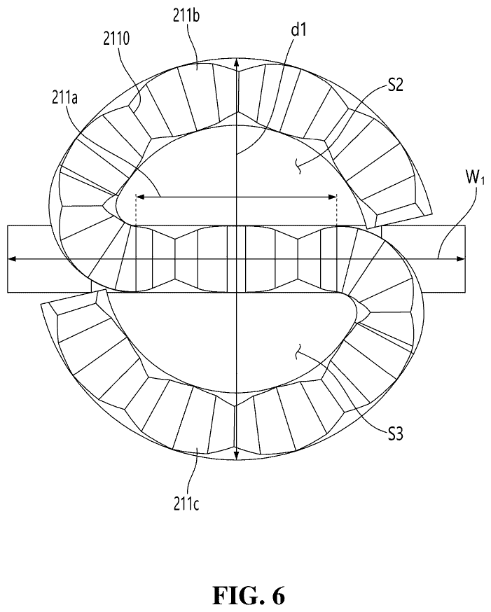

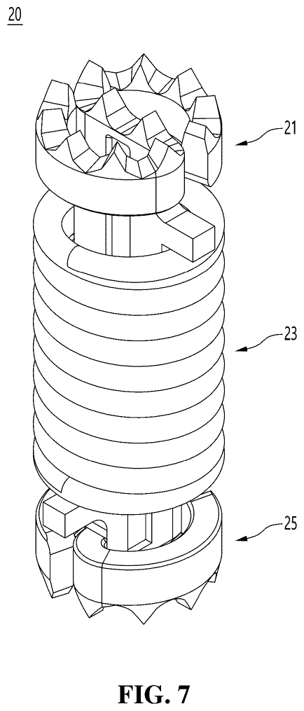

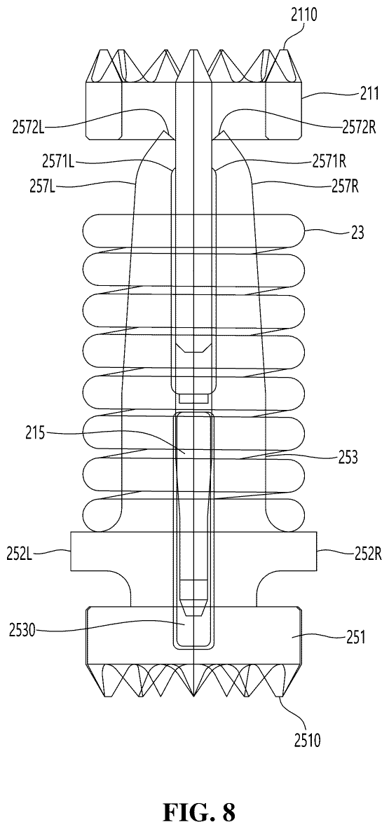

That is, since the spring contact 20 is inserted into the holes h₁, h₂, and h₃, one end of the spring contact 20 is in contact with the lead of the semiconductor device and the other end of the spring contact 20 is in contact with the pad of the test device, and thus the spring contact 20 may exert an elastic force in a pressing direction. The detailed configuration of the spring contact 30 according to the exemplary embodiment of the present invention will be described below in more detail with reference to FIGS. 3 to 8.

Meanwhile, the body may include bases 51, 53, and 54 forming an exterior of the test socket, and an elastic insulator 52 filled and then hardened in the bases 51, 53, and 54 to form an elastic force.

The bases 51, 53, and 54 may be formed by the first surface 51, the second surface 53, and a frame 54, and since the holes pass through the first surface 51 and the second surface 52, the holes may be formed while passing through the elastic insulator 52 filled inside the bases 51, 53, and 54.

For example, the first surface 51 and the second surface 52 are made of a polyimide (Pi) film, which allows the test socket of the embodiment to stably function even in a high-temperature environment when performing a burn-in test to check whether a semiconductor integrated circuit (IC) stably operates for a long period of time at high temperatures.

Further, for example, the frame 54 may be made of stainless steel (SUS) or a composite material (FR4) or the like composed of epoxy resin and glass fiber having flame retardant (FR) properties. Accordingly, the test socket of the embodiment may stably function even in high-temperature environments or ensure electrical insulation performance.

Meanwhile, the spring contact 20 of the embodiment has a structure in which two contact pins 21 and 25 are elastically coupled by a spring 23, and the contact pins 21 and 25 may include shoulders 212 and 512, respectively.

Each of the shoulders 212 and 512 may be caught on the first surface 51 and the second surface 53 to prevent the spring contacts 30 from being detached from the holes h₁, h₂, and h₃ after being inserted into the holes.

More specifically, when an LGA lead 17 comes into contact with an end portion of the spring contact 20 protruding from the first surface 51 by the pressing of a substrate 15, and an end portion of the spring contact 20 protruding from the second surface 53 comes into contact with the pad of the test device, as the shoulder 512 comes into contact with the second surface 52, the spring contact 20 may be elastically compressed.

In the above-described structure, for example, the diameters of the holes h₁, h₃, and h₂ formed in the first surface 51, the second surface 53, and the elastic insulator 52 may be the same.

Further, in the above-described structure, for example, the diameters of two holes selected from the diameter of the hole h₁ formed in the first surface 51, the diameter of the hole h₃ formed in the second surface 53, and the diameter of the hole h₂ formed in the elastic insulator 52 may be differently formed.

That is, in the embodiment, the spring contact 20 may be caught and fixed by the first surface 51 and the second surface 53.

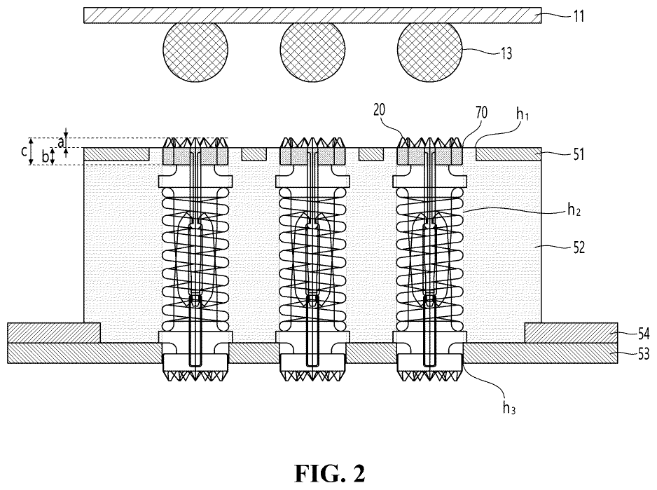

Generally, the LGA lead 17 in FIG. 1 is formed in a flat pad form and thus has a wider contact area with the contact pins in the test socket than a ball grid array (BGA) lead 13 in FIG. 2.

When a silicone-based member is used to fix a position of the spring contact for testing the LGA lead 17 as shown in FIG. 2, since the silicone-based member may adhere to the LGA lead 17, or the silicone-based member may fall off as long-term testing is repeated, the durability of the test socket may deteriorate.

Accordingly, in the embodiment, the spring contact 30 for testing the LGA lead 17 may be fixed by the first surface 51 and the second surface 53.

Meanwhile, a step hole (not shown) may be formed in the second surface 53. The step hole may be provided by forming a step in a direction from the second surface 53 toward the first surface 51. In a shape of the step hole, a diameter of the step hole may be formed greater than the diameters of the holes h₁, h₂, and h₃.

As the step hole distributes a load of the test socket which is repeatedly pressed between the lead of the semiconductor device and the pad of the test device, the step hole may further enhance the durability of the test socket which is an exemplary embodiment of the present invention.

Meanwhile, the spring contact 20 of the embodiment may include head portions 211 and 251 that are pressed into contact with the lead, and end portions of the head portions 211 and 251 protrude a certain portion a from the first surface 51 to ensure reliable contact with the lead.

More specifically, in the test socket of the embodiment, the spring contact 20 has a structure fixed by a film 51 according to a shape (PAD) of the LGA lead 17 as described above.

In this structure, in order to ensure reliable contact with the lead 17, a length of the portion a protruding from the first surface 51 of the head portions 211 and 251 may be longer than vertical lengths of tip portions 2110 and 2510. Preferably, the protruding portion a may protrude more than half of the vertical lengths c of the head portions 211 and 251. The vertical length may mean heights of the tip portions 2110 and 2510 formed along a longitudinal direction of the spring contact 20.

FIG. 2 is a view illustrating a test socket for BGA leads according to the exemplary embodiment of the present invention.

Hereinafter, the present invention will be described with reference to FIG. 2, but overlapping contents described for FIG. 1 will be omitted.

A first member 70 may be bonded to one end of the spring contact 20 of the embodiment. The one end of the spring contact may mean a contact end of the spring contact 20 located on the first surface 51 which comes into contact with the lead of the semiconductor device while the spring contact 30 is inserted into the holes h₁, h₂, and h₃.

The first member 70 may be provided between an inner surface of the hole h₁ formed in the first surface 51 and a circumference of one end of the spring contact 20. The first member 50 may be compressed, and rolled into and hardened between the circumference of one end of the spring contact 30 and the hole h₁ by being made of a flexible material and provided on one end surface of the spring contact 30, and thus may be provided between the inner surface of the hole h₁ formed in the first surface 51 and the circumference of one end of the spring contact 30. Accordingly, the first member 70 may be provided with a silicone-based material whose properties change due to heat.

More specifically, in the embodiment, the diameter of the hole h₁ formed in the first surface 51 may be greater than the diameters of the holes h₃ and h₂ formed in the second surface 53 and the elastic insulator 52. Further, the diameter of the hole h₁ formed in the first surface 51 may be greater than the maximum diameter of the spring contact 20, and the diameters of the holes formed in the second surface 53 and the elastic insulator 52 may be the same. In addition, the diameters of the holes formed in the second surface 53 and the elastic insulator 52 may be smaller than the maximum diameter of the spring contact.

Since the maximum diameter of the spring contact 20 may be formed by widths of the shoulders 212 and 252 as described above, the maximum diameter of the spring contact 20 may be the same as the widths of the shoulders 212 and 252.

In this structure, the first member 70 may be provided on the inner surface of the hole d₁ formed in the first surface 51 and on an end portion of the spring contact 20.

For example, there may be a case where the hole d₁ formed in the first surface 51 is filled with the elastic insulator 52 and a case where the hole h₁ formed in the first surface 51 is not filled.

When the hole d₁ formed in the first surface 51 is not filled with the elastic insulator 52, the inner surface of the hole d₁ of the first surface 51 and an upper end surface of the elastic insulator 52 may form a step, and the first member 70 may be pressed and then rolled into and hardened in the inner surface of the hole d₁ of the first surface 51, and thus may fill the end portion of the spring contact 20 and the inner surface of the hole d₁ formed in the first surface 51.

Further, when the hole d₁ formed in the first surface 51 is filled with the elastic insulator 52 as in the embodiment, the first member 70 is pressed and then rolled into and hardened in the inner surface of the hole d₂ formed in the elastic insulator 52 on the first surface, and thus may fill the end portion of the spring contact 20 and the inner surface of the hole d₁ in the first surface 51 of the elastic insulator 52.

Generally, since the BGA lead 13 is made of a spherical solder ball, the BGA lead 13 may be pressed deeper toward the test socket compared to the LGA lead 17 in FIG. 1 when a substrate 11 is compressed.

Accordingly, it is advantageous for a length of the spring contact (or a length of a contact end) to increase for stable contact. This is because when the length of the spring contact (or the length of the contact end) is insufficient, the spring contact may not be pressed sufficiently for accurate testing when coming into contact with an upper surface of a housing (for example, first surface configurations in FIG. 1).

However, as described above, when the length of the spring contact (or the length of the contact end) increases, electrical characteristics may deteriorate, and the spring contact may not be suitable for testing a high-speed signal semiconductor device.

Accordingly, in the case of the embodiment, as the elastic insulator 52 and the first member 70 made of a flexible material or the first member 70 is provided in the hole d₁ formed in the first surface 51 so that the spring contact 20 may be sufficiently pressed with the BGA lead 13 while minimizing the length of the spring contact 20, upper portion contraction control of the socket body including the elastic insulator 52 may be facilitated.

Unlike the embodiment, when the socket body is made of a non-elastic material such as a general spring contact pin-type socket, since the socket body does not contract, the presence of the first member 70 may act as a factor that hinders the contraction force of the spring contact.

However, as described above, since the test socket of the embodiment is a test socket in which the advantages of a general spring contact pin-type socket (a poco pin-type socket) and a silicone rubber-type socket are combined, durability may be enhanced by controlling the upper portion contraction of the socket body 10 through the first member 70.

Further, since the first member 70 may enhance the coaxial alignment of the contacts 30 in the body 10 containing an elastic material, the positional alignment of the contact portion of the contacts 20 may be enhanced.

In addition, as the first member 70 is formed of a silicone-based material, since the insulation performance between fine pitches is enhanced, noise may be reduced when testing a high-speed signal semiconductor device.

In addition, the first member 70 may prevent the electrical performance from deteriorating due to foreign substances entering between the spring contact 20 and the hole formed in the socket in a semiconductor IC test environment.

The first member 70 may be appropriately selected to meet customer needs with a shore hardness ranging from 20A to 80A. When the hardness of the first member 70 is outside the above range, it may be difficult to achieve above-described effects.

For example, when the hardness of the first member 70 is higher than the above range, the hardness may act as a factor which hinders the elastic force of the contact 20 and thus may require a greater load when testing, and when the hardness of the first member 70 is lower than the above range, it may be difficult to achieve the above-described various effects. That is, when the hardness of the first member 70 is outside the above range, the test socket may not meet customer's load-related performance requirements, or the durability of the test socket may deteriorate.

Meanwhile, in this structure, the spring contact 20 of the embodiment may include head portions 211 and 251 which are pressed into contact with the lead, and end portions of the head portions 211 and 251 protrude a certain portion a from the first surface 51 to ensure reliable contact with the lead.

More specifically, in the test socket of the embodiment, the spring contact 20 is structured to be fixed by the silicone-based first member 70 according to a shape (BALL) of the BGA lead 13 as described above.

In this structure, since the lead 13 is pressed along with the first member 70 by the pressing of the substrate 11, reliable contact may be sufficiently secured even when the spring contact in FIG. 1 protrudes slightly more than the degree to which it protrudes from the first surface.

That is, in the socket structure for testing the BGA leads as in the embodiment, it is preferable that the length of the protruding portion a is similar to the vertical lengths of the tip portions 2110 and 2510. The vertical length may mean heights of the tip portions 2110 and 2510 formed along the longitudinal direction of the spring contact 20, and similar means that errors which may occur during assembly of the test socket may be taken into account, and ideally, the length of the protruding portion a may be the same as the vertical lengths of the tip portions 2110 and 2510.

FIGS. 3 to 8 are views illustrating the spring contacts applied in FIGS. 1 and 2.

Hereinafter, the present invention will be described with reference to FIGS. 1 to 8.

The spring contact 20 according to the embodiment includes a first contact pin 21, a second contact pin 25, and a spring 23. The spring contact 20 may be assembled so that the first contact pin 21 and the second contact pin 25 intersect each other based on the spring 23 to be elastically supported by the spring 23.

The spring 23 of the embodiment may be a coil-shaped compression spring having a certain thickness based on an outer diameter and an inner diameter of the spring 23 and a certain length along the longitudinal direction of the spring contact 23, and the spring 23 may be located between the first contact pin 21 and the second contact pin 25 in the spring contact 20 and may provide a restoring force for returning each of the contact pins 21 and 25 to its pre-compressed position based on the spring 23 when the first contact pin 21 and the second contact pin 25 are compressed in the longitudinal direction

In this structure, when testing the semiconductor device IC through the test socket to which the spring contact 20 of the embodiment is applied, when the head portion 211 of the first contact pin 21 comes into contact with a circuit pattern of a test printed circuit board installed in the test device, as the head portion 251 of the second contact pin 25 comes into contact with the contact ball or land of the BGA-type or LGA-type semiconductor IC, the test printed circuit board and the semiconductor IC may be electrically connected.

The first contact pin 21 and the second contact pin 25 of the embodiment may be provided as contact pins having the same size and shape. The two contact pins 21 and 25 may be assembled in the longitudinal direction to be elastically supported by the spring 23 and distinguished as the first contact pin 21 and the second contact pin 23 depending on an assembly position. Accordingly, hereinafter, the present invention will be described based on the first contact pin 21.

The first contact pin 21 may be composed of the head portion 211, a body portion 213, leg portions 215, catch members 217, and the shoulders 212.

The head portion 2111 may be composed of a plate-shaped strip having the same length on the left and right with respect to a center of the body portion 213 at an upper end of the body portion 213 and formed with an upper tip portion 2110 along an upper tip, and the plate-shaped strip may include a first strip section 211b and a second strip section 211c having the same distance on the left and right from a plate-shaped strip center portion 211a.

That is, the head portion 211 may be provided in a cylindrical shape having an overall diameter d₁ by rolling each of the first strip section 211b and the second strip section 211c in a semicircular shape based on the center portion 211a. Further, it is preferable that the width of the center portion 211a forming the reference for rolling each strip corresponds to the width of the body portion 213. This is because a defect rate in stamping the contact pin may increase when the width of the center portion 211a is smaller or greater than the width of the body portion 213.

Meanwhile, the head portion 211 may be provided in a cylindrical crown shape by the tip portion 2110. With this shape or configuration of the head portion 211, the ball portion of the BGA may be stably grounded and may press the test socket, thereby enhancing test accuracy and also securing a sufficient contact area with the lead of the LGA.

The body portion 213 may have a certain width and thickness and include a guide portion 2130 formed along a longitudinal direction of the body portion 213 and shoulders 212L and 212R formed to protrude in a width direction of the body portion.

The shoulders 212L and 212R may be respectively provided at positions symmetrical to each other based on the body portion 213. The shoulder 212L protruding in a direction perpendicular to the body portion 213 from one side of the body portion 213 and the shoulder 212R protruding in a direction perpendicular to the body portion 213 from the other side of the body portion 213 may each have the same degree of protrusion, shape, size, thickness, width, and the like and thus may be provided in a symmetrical shape based on the body portion 213. Accordingly, hereinafter, the present invention will be described based on the shoulder 213L.

The shoulder 213L may support the elasticity of the spring 23 in the spring contact 20 of the embodiment.

More specifically, the spring contact 20 may support the elasticity of the spring 23 by shoulders 213L and 213R of the first contact pin 21 and shoulders 253L and 253R of the second contact pin 25.

In the above-described structure, a distance between end portions of the shoulder 213L protruding from one side of the body portion 213 and the shoulder 213R protruding from the other side of the body portion 213 may be defined as a width w₁ of the shoulders 213L and 213R, and the width w₁ of the shoulders may be formed greater than at least the inner diameter of the spring, thereby supporting both ends of the spring 23.

Preferably, as the width w₁ of the shoulder may form the maximum diameter of the spring contact 20 and may be formed greater than the diameters of the holes formed in the test socket, it is possible to prevent the spring contact 20 from being detached from the test socket when performing repeated operations through the test socket.

Further, when manufacturing the test socket, since it is advantageous to form a diameter of the pin hole small to reduce a pitch interval of the spring contact, the width w₁ of the shoulders may be formed within a range that is greater than the inner diameter of the spring and smaller than the outer diameter of the spring.

The guide portion 2130 may be formed in a groove shape along the longitudinal direction of the body portion 213. Accordingly, a thickness formed by the guide portion 2130 is formed smaller than a thickness of the body portion.

The guide portion 2130 may guide the up-down movement of the second contact pin 25 when the second contact pin 25 is cross-coupled to the first contact pin 21. In this structure, when the spring contact 20 is compressed or when the spring contact 20 is assembled, a catch member 257 of the second contact pin 25 may move along the longitudinal direction of the body portion 213 along the guide portion 2130 of the first contact pin 21.

In addition, an inclined surface 2131 may be formed at a portion where a pair of leg portions 215 extend from the body portion 213 so that the contact pins 21 and 25 may be easily cross-coupled.

The inclined surface 2131 may allow the catch member 217 described below to easily come into contact with the guide portion 2130, and in this structure, when each pin is cross-coupled with the spring 23 therebetween, the guide portion 2130 of each other may be easily inserted into a space S1 between the respective leg portions.

Meanwhile, the leg portions 215 may be formed by extending in a direction opposite to the head portion 211 along the longitudinal direction of the body portion 213. The leg portions 215 may be provided as a pair of leg portions 213L and 213R that are symmetrical to each other based on a center line of the body portion 213.

For example, the pair of leg portions 213L and 213R may have a certain elastic force so that a width w₂ between the leg portions increases when the spring contact 20 is compressed or when the contact pins 21 and 25 are assembled.

More specifically, the width w₂ between the pair of leg portions 213L and 213R may be formed greater than the thickness of the body portion 213. In this structure, when the spring contact 20 is compressed, the first contact pin 21 and the second contact pin 25 may move a certain distance relative to each other in a direction of compressing the spring 23.

Meanwhile, a pair of catch members 217L and 217R may be formed at end portions of the pair of leg portions 213L and 213R.

The shortest distance w₃ between the catch member 217L formed on the leg portion 215L at one side and the catch member 217R formed on the leg portion 215R at the other side may be formed smaller than the thickness of the body portion, and preferably, the shortest distance w₃ between the pair of catch members may be formed to be greater than or equal to the thickness of the guide portion.

This is because surfaces 2172 and 2572 forming the shortest distance w₃ between the pair of catch members in the contact pins 21 and 25 form an electrical contact surface of each of the contact pins 21 and 25 in the spring contact pin 20. When the shortest distance w₃ between the pair of catch members is formed smaller than the thickness of the guide portion 2130, each of the contact pins 21 and 25 of the spring contact pin 20 is prone to jamming, and thus the possibility of malfunction increases.

Accordingly, since the shortest distance w₃ between the pair of catch members is formed to be greater than or equal to the thickness of the guide portion, the spring contact pin 20 forms four electrical contact surfaces through the contact surfaces 2172 and 2572 of each of the contact pins 21 and 25, and at least one of contact surfaces 2172L and 2172R of one contact pin 21 may be in electrical contact with a bottom surface of the guide portion 2530 of the other contact pin 23.

Meanwhile, the catch member 217 may include corner portions 2173, the contact surfaces 2172 extending from the corner portions 2173 at a certain angle and facing each other, and inflection surfaces 2171 forming steps from the contact surfaces 2172 toward the outside of the space S1.

In this structure, since the guide surface 2172 is in contact with the inclined surface 2130 and is coupled when each of the contact pins is assembled, the pair of contact pins may be easily assembled, and the inflection surface 2171 may be caught on an upper end of the inclined surface 2130 when each of the contact pins is assembled, thereby preventing the pair of contact pins from being unintentionally separated after being coupled.

Meanwhile, the corner portions 2173 may be located in spaces S2 and S3 formed as the head portion 211 is provided in the crown shape, when the spring contact 20 is compressed in the pressing direction.

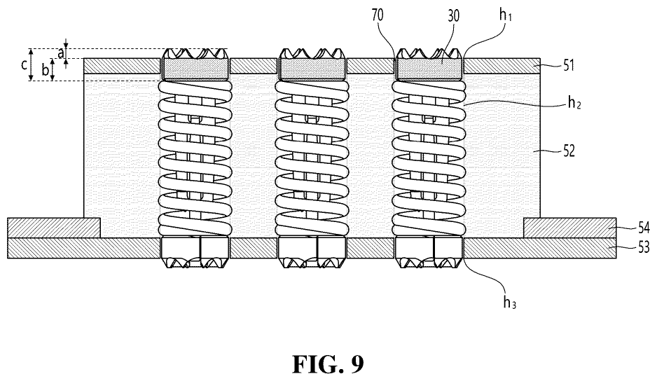

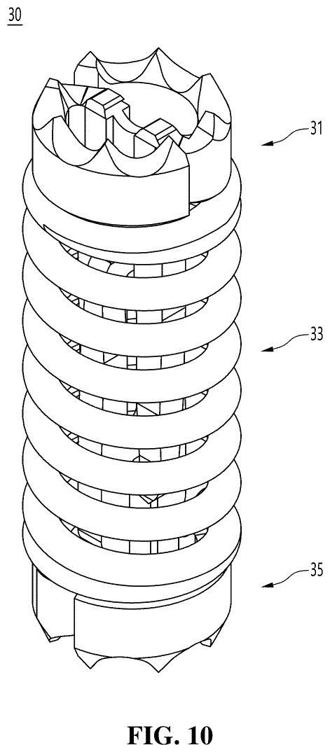

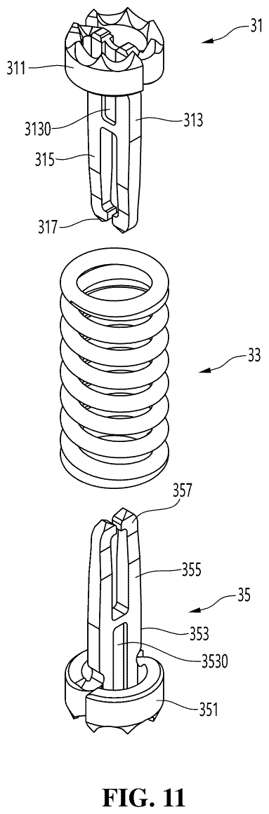

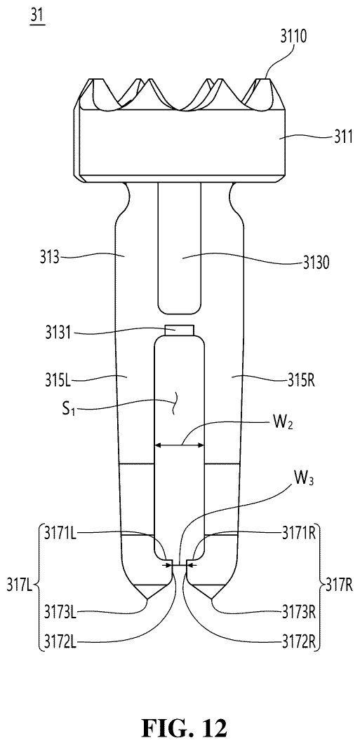

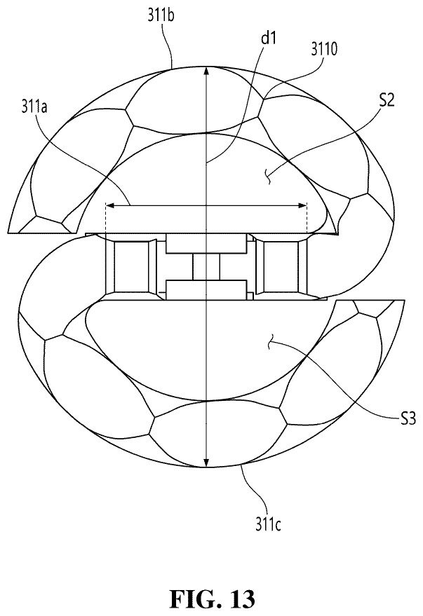

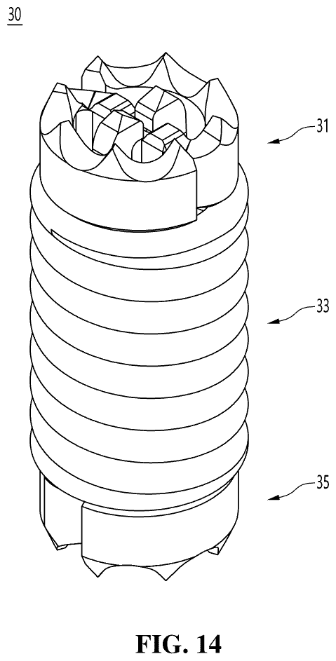

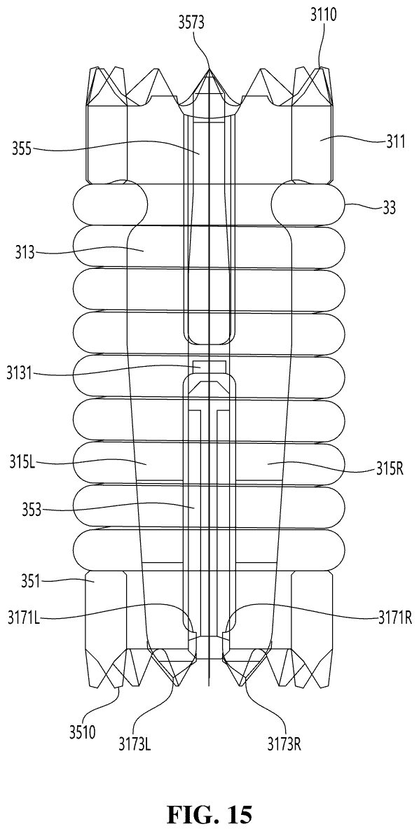

FIG. 9 is a view illustrating a test socket according to the exemplary embodiment of the present invention, and FIGS. 10 to 15 are views illustrating spring contacts applied in FIG. 9.

Hereinafter, the present invention will be described with reference to FIGS. 9 to 15, and contents overlapping the above-described contents will be omitted.

The test socket of the embodiment may include a body and contacts 30. The body may have holes formed through a first surface 51 facing a lead of a semiconductor device and a second surface 53 facing a pad of the test device. Diameters of holes h₁, h₂, and h₃ are formed to be similar to the diameter of the contact 20, and thus the spring contact 30 may be inserted into the holes h₁, h₂, and h₃.

Meanwhile, the body may include bases 51, 53, and 54 forming an exterior of the test socket, and an elastic insulator 52 which is filled and then hardened in the bases 51, 53, and 54 to form an elastic force.

For example, the first surface 51 and the second surface 52 may be made of a polyimide (Pi) film, and a frame 54 may be made of stainless steel (SUS) or a composite material (FR4) or the like composed of epoxy resin and glass fiber having flame retardant (FR) properties.

A first member 70 may be bonded to one end of the spring contact 30 of the embodiment. The one end of the spring contact may mean a contact end of the spring contact 30 located on the first surface 51 which comes into contact with the lead of the semiconductor device while the spring contact 30 is inserted into the holes h₁, h₂, and h₃.

The first member 70 may be provided between an inner surface of the hole h₁ formed in the first surface 51 and a circumference of one end of the spring contact 30. The first member 50 may be compressed and rolled into and hardened between the circumference of one end of the spring contact 30 and the hole d₁ by being made of a flexible material and provided on one end surface of the spring contact 30, and thus may be provided between the inner surface of the hole d₁ formed in the first surface 51 and the circumference of one end of the spring contact 30. Accordingly, the first member 70 may be provided with a silicone-based material whose properties change due to heat.

More specifically, in the case of the embodiment, a diameter of the hole h₁ formed in the first surface 51 may be the same as diameters of the holes d₃ and d₂ formed in the second surface 53 and the elastic insulator 52. Further, the diameter of the hole d₁ formed in the first surface 51 may be smaller than the maximum diameter of the spring contact 30. Since the maximum diameter of the spring contact 30 may be formed by an outer diameter of a spring 33, the maximum diameter of the spring contact 30 may be the same as the outer diameter of the spring 33.

In this structure, the spring contact 30 may be fixed in the test socket by the outer diameter of the spring 33 pressing the inner surface of the hole d₁ formed in the elastic insulator 52 made of a flexible material.

However, when the spring contact 30 is fixed to the hole formed in the test socket by only a frictional force generated while the outer diameter of the spring 33 presses the inner surface of the hole formed in the elastic insulator 52, there is high possibility that the spring contact 30 may be detached due to repeated operations of the test socket.

Accordingly, in the embodiment, as described above, since the first member 70 is provided on the inner surface of the hole d₁ formed in the first surface 51 and on one end of the spring contact 30 (on a head portion 311) and prevents the spring contact 30 from being detached due to repeated operations of the test socket, the test reliability and durability of the test socket may be enhanced.

Of course, in terms of fixing the spring contact 30, when the first member 70 is provided on the inner surface of the hole d₂ formed in the second surface 53 and on the other end (on a head portion 351) of the spring contact 30, or the first member 70 is provided on each of the hole d₁ formed in the first surface 51 and the hole d₂ formed in the second surface 53 and fixes both one end and the other end of the spring contact 30, a fixing force of the spring contact 30 may further increase, but it may also act as a factor which hinders a contraction force of the spring contact 30.

Accordingly, in order to effectively achieve the objectives of controlling the upper portion contraction of the socket body, preventing foreign substances from entering the test socket, enhancing coaxial alignment, and the like, as described above, it is preferable that the first member 70 is provided on the inner surface of the hole d₁ formed in the first surface 51 and on one end (on the head portion 311) of the spring contact 30.

Further, the diameter of the hole d₁ formed in the first surface 51 may be greater than the diameters of the holes d₃ and d₂ formed in the second surface 53 and the elastic insulator 52, and the diameter of the hole d₁ formed in the first surface 51 may be greater than the maximum diameter of the spring contact 30. In addition, the diameter of the holes d₃ and d₂ formed in the second surface 53 and the elastic insulator 52 may also be greater than the maximum diameter of the spring contact 30. Since the maximum diameter of the spring contact 30 may be formed by the outer diameter of the spring 33, the maximum diameter of the spring contact 30 may be the same as the outer diameter of the spring 33.

In this structure, the spring contact 30 may be fixed to the holes formed in the test socket by the first member 70 as described above.

Meanwhile, the head portions 311 and 351 of the spring contact 30 according to the exemplary embodiment of the present invention may be formed by rolling a plate-shaped strip, and in this shape, the maximum diameter d₁ of the head portion 311 and 351 may be formed with a range that is greater than the inner diameter of the spring 33 and smaller than the outer diameter of the spring.

The contact 30 of the embodiment may include the configurations of spring contact pins. That is, the spring contact 30 may include two contact pins 31 and 35 and the spring 33 providing a physical elastic force to the contact 30.

More specifically, the contact 30 may include a pair of contact pins 31 and 35 and the spring 33, and the spring 33 may be coupled between the pair of contact pins 31 and 35 to provide an elastic force to the contact 30.

The spring 33 may be a coil-shaped compression spring having a certain length along the longitudinal direction of the contact 30, and the spring 33 may be located between the first contact pin 31 and the second contact pin 35 in the contact 30 and provide a restoring force for returning each of the contact pins 31 and 35 to its pre-compressed position based on the spring 33 when the first contact pin 31 and the second contact pin 35 are compressed in the longitudinal direction

In the embodiment, the pair of contact pins 31 and 35 may be provided with the same shape and coupled in an intersecting direction. Further, the pair of contact pins 31 and 35 may also be provided with different shapes and coupled with the spring therebetween.

Hereinafter, the pair of contact pins are referred to as the first contact pin 31 and the second contact pin 35, and in the embodiment, since the pair of contact pins 31 and 35 are provided in the same shape, the configuration of the contact pin will be described based on the first contact pin 31.

The contact pin 31 may include a body portion 312, a head portion 311, and leg portions 313.

The body portion 312 is formed with a guide portion 3130 having a certain width and length in the longitudinal direction formed at a center between both sides thereof, a catch having a step (not shown) may be formed at a lower end portion of the guide portion 3130, and an upper end of the guide portion 3130 extends to an upper end of the head portion 311. The catch (not shown) means a configuration in which an end portion of a catch member 357 of the second contact pin 35 is caught when the second contact pin 35 is coupled to the first contact pin 31 in the intersecting direction.

The head portion 311 may be composed of a plate-shaped strip having the same length on the left and right with respect to the center of the body portion 313 at an upper end of the body portion 313 and formed with a tip portion 3110 along an upper tip, and the plate-shaped strip may include a first strip section 311b and a second strip section 311c having the same distance on the left and right from a center portion 311a of the body portion 313.

That is, the head portion 311 may be provided in a cylindrical shape having an overall diameter d₁ by rolling each of the first strip section 311b and the second strip section 311c in a semicircular shape based on the center portion 311a.

Meanwhile, the head portion 311 may be provided in a cylindrical crown shape by the tip portion 3110. With this shape or configuration of the head portion 311, the ball portion of the BGA may be stably grounded and may press the test socket, thereby enhancing test accuracy and also securing a sufficient contact area with the lead of the LGA.

Meanwhile, a pair of leg portions 315 may be formed to symmetrically extend left and right from the body portion 313, and since a certain space S1 is formed between the pair of leg portions, each of the leg portions may be guided when the first contact pin 31 and the second contact pin 35 are coupled in a direction intersecting each other.

Further, when assembling the contact 30, an inclined surface 3131 may be formed at a portion where the pair of leg portions 315 extend from the body portion 313 so that the second contact pin 35 may be easily assembled in a direction intersecting the first contact pin 31.

More specifically, a catch member 317 may be formed at an end portion of the leg portion 315, and the catch member 317 may include corner portions 3173 which are located on the same plane as the tip portion 3110 and are in electrical contact with the leads when the contact 30 is compressed in the pressing direction, guide surfaces 3172 extending from the corner portions 3173 at a certain angle and facing each other, and inflection surfaces 3171 forming steps from the guide surfaces 3172 toward the outside of the space S1.

In this structure, since the guide surface 3131 is in contact with and coupled to the inclined surface 3120 when each of the contact pins is assembled, a pair of contact pins may be easily assembled, and the inflection surface 3131 is caught on a catch (not shown) when each of the contact pins is assembled, thereby preventing the pair of contact pins from being unintentionally separated after being coupled.

Meanwhile, the corner portions 3173 may be located in spaces S2 and S3 formed as the head portion 311 is provided in the crown shape, when the spring contact 30 is compressed in the pressing direction.

That is, in the above-described structure, when the spring contact 30 is maximally compressed, corner portions 3573 of the second contact pin 35 are located on the same plane as the tip portion 3110 of the first contact pin 31, thereby not only enhancing the electrical contact performance of the test socket, but also enhancing the contact performance with the lead.

Although various embodiments of the present invention have been described above in detail, those skilled in the art will understand that various modifications are possible in the above-described embodiments without departing from the scope of the present invention. Accordingly, the scope of the present invention should not be limited to the above-described embodiments, but should be defined by the following claims as well as those equivalents of the claims.

1. A test socket comprising:
a base including a first surface facing a lead of a semiconductor device and a second surface facing a pad of a test device;
an elastic insulator filled and then hardened in the base to form an elastic force;
holes passing through the first surface, the second surface, and the elastic insulator; and
a spring contact inserted into the holes and having one end that is in contact with the lead of the semiconductor device and the other end that is in contact with the pad of the test device to exert an elastic force in a pressing direction,
wherein the spring contact includes a shoulder having a width greater than diameters of the holes, and
the shoulder is in contact with the elastic insulator.

2. The test socket of claim 1, wherein the width of the shoulder forms the maximum width of the spring contact.

3. The test socket of claim 1, wherein the width of the shoulder is greater than an inner diameter of a spring and smaller than an outer diameter of the spring.

4. The test socket of claim 2, wherein the diameters of the holes formed in the first surface, the second surface, and the elastic insulator are the same.

5. The test socket of claim 2, wherein the diameters of two holes selected from the diameter of the hole formed in the first surface, the diameter of the hole formed in the second surface, and the diameter of the hole formed in the elastic insulator are different from each other.

6. The test socket of claim 2, further comprising a first member made of an elastic material provided on an inner surface of the hole formed in the first surface to fix an end portion position of the spring contact.

7. A test socket comprising:
a base including a first surface facing a lead of a semiconductor device and a second surface facing a pad of a test device;
an elastic insulator filled and then hardened in the base to form an elastic force;
holes passing through the first surface, the second surface, and the elastic insulator; and
a spring contact inserted into the holes and having one end that is in contact with the lead of the semiconductor device and the other end that is in contact with the pad of the test device to exert an elastic force in a pressing direction,
wherein the spring contact includes a shoulder having a width greater than at least one of diameters of the holes formed in the first surface, the second surface, and the elastic insulator, and
the shoulder is in contact with the elastic insulator.

8. The test socket of claim 7, wherein the diameter of the hole formed in the first surface is greater than the diameters of the holes formed in the second surface and the elastic insulator.

9. The test socket of claim 8, wherein the diameter of the hole formed in the first surface is greater than the width of the shoulder.

10. The test socket of claim 9, wherein the diameters of the holes formed in the second surface and the elastic insulator are smaller than the width of the shoulder.

11. The test socket of claim 10, further comprising a first member made of an elastic material provided on an inner surface of the hole formed in the first surface to fix an end portion position of the spring contact.

12. The test socket of claim 10, wherein the elastic insulator is provided between an inner surface of the hole formed in the first surface and an end portion of the spring contact.

13. The test socket of claim 12, further comprising a first member made of an elastic material provided on the inner surface of the hole formed in the elastic insulator to fix an end portion position of the spring contact.

14. A test socket comprising:
a base including a first surface facing a lead of a semiconductor device and a second surface facing a pad of a test device;
an elastic insulator filled and then hardened in the base to form an elastic force;
holes passing through the first surface, the second surface, and the elastic insulator; and
a spring contact inserted into the holes and having one end that is in contact with the lead of the semiconductor device and the other end that is in contact with the pad of the test device to exert an elastic force in a pressing direction,
wherein the spring contact includes a spring having a diameter greater than diameters of the holes, and
the spring presses an inner surface of the hole formed in the elastic insulator.

15. The test socket of claim 14, wherein the diameter of the spring forms the maximum diameter of the spring contact.

16. The test socket of claim 15, wherein the spring contact includes a head portion that is in contact with the lead of the semiconductor device and the pad of the test device, and
the head portion is formed by rolling a plate-shaped strip.

17. The test socket of claim 16, wherein the maximum diameter of the head portion is greater than an inner diameter of the spring and smaller than an outer diameter of the spring.

18. The test socket of claim 14, further comprising a first member made of an elastic material provided on an inner surface of the hole formed in the first surface or an inner surface of the hole formed in the second surface to fix an end portion position of the spring contact.

19. The test socket of claim 14, further comprising a first member provided on an inner surface of the hole formed in the first surface and an inner surface of the hole formed in the second surface to fix an end portion position of the spring contact.

20. A test socket comprising:
a base including a first surface facing a lead of a semiconductor device and a second surface facing a pad of a test device;
an elastic insulator filled and then hardened in the base to form an elastic force;
holes passing through the first surface, the second surface, and the elastic insulator;
a spring contact inserted into the holes and having one end that is in contact with the lead of the semiconductor device and the other end that is in contact with the pad of the test device to exert an elastic force in a pressing direction; and
a first member made of an elastic material provided on at least one of an inner surface of the hole formed in the first surface and an inner surface of the hole formed in the second surface to fix an end portion position of the spring contact,
wherein the spring contact includes a spring having a diameter smaller than diameters of the holes.
